(19) United States
(12) Patent Application Publication
(10) Pub. No.: US 2025/0377381 A1
(43) Pub. Date: Dec. 11, 2025

(54) MEASUREMENT DEVICE HAVING LIMIT GAUGES

(71) Applicant: Fluke Corporation, Everett, WA (US)

(72) Inventors: Rick Van Bommel, Eindhoven (NL); Scott M. Tsukamaki, Bothell, WA (US); Wei Huang, Shanghai (CN)

(21) Appl. No.: 18/821,535

(22) Filed: Aug. 30, 2024

Related U.S. Application Data
(63) Continuation of application No. PCT/CN2024/098310, filed on Jun. 10, 2024.

(51) Int. Cl. G01R 15/12

(52) U.S. Cl. CPC G01R 15/125

(57) ABSTRACT

A measurement device is disclosed, which may include or wirelessly connected to sensors or sensing devices for sensing an electrical property. The measurement device can receive user input, e.g., from physical UI components, to set a reference range of values and measures the electrical property of a device under test. Under a limit gauge operation mode, if the measured value is outside the reference range, the measurement device can produce an alert to notify its users.

### CROSS-REFERENCE TO RELATED APPLICATIONS

This application is a continuation of PCT Application Number PCT/CN2024/098310, filed Jun. 10, 2024, and entitled “MEASUREMENT DEVICE HAVING LIMIT GAUGES”, which is hereby incorporated by reference in its entirety.

### BACKGROUND

### Technical Field

The present disclosure generally relates to test or measurement devices, and more particularly to electrical measurement devices that provide an alert when a measured electrical parameter is outside an expected range of values.

### Description of the Related Art

Electrical measurement devices such as digital multimeters (“DMM”) function to measure different electrical parameters as needed for service, troubleshooting, and maintenance. Such parameters may include AC voltage and current, DC voltage and current, resistance, continuity, etc. A DMM may also measure other parameters, such as capacitance and temperature. A DMM is often a handheld unit having a rotary knob by which various functions are selected. Multiple lead jacks may be provided in the case (i.e., housing) of the unit for receiving test leads. The specific jack or jacks used may depend on the function that has been selected. A display, e.g., an LCD display, provides a reading of the measured parameter.

The plurality of lead jacks or input terminals includes a common input terminal and one or more test input terminals. The test input terminals may include, for example, a volt/ohms input terminal and one or more amps or microamps input terminals. The common input terminal is coupled to a reference node of the DMM, e.g., a ground, and a lead of a test probe is inserted into one of the test input terminals for the respective measurement tasks. For example, to measure an electrical current, a DMM user must disconnect the test probe from the volt/ohms terminal and connect it to the microamps terminal. Some DMMs may include a single test input terminal. That is, a current measurement and a voltage measurement can be conducted using the same test input terminal under separate measurement modes selected by a user through a user interface of the DMMs. Further, some DMMs may include test terminals different from test probes and input lead jacks. For example, DMMs may include a contact-free test end, e.g., a U-shaped recess portion, having measurement sensors embedded therein. The measurement sensors function to measure the electrical parameters of an object received in the U-shaped recess portion without galvanically contacting the object.

### BRIEF SUMMARY

Disclosed herein is a measurement device that provides an alert, e.g., to a user of the measurement device, based on whether a measured value is within a specified range of values (i.e., a “limit gauge”).

In some embodiments, the measurement device includes one or more sensors configured to measure an electrical property, an output that produces a user-perceptible feedback, one or more processors, and a storage device that stores instructions for the one or more processors. The instructions cause the one or more processors to receive input, e.g., user input, that provides a reference range of values of the electrical property. A first measurement of the electrical property of a first component of a plurality of components is received via the one or more sensors. A determination is made whether a value of the first measurement is outside the reference range of values. In response to determining that the value is outside the reference range of values, the output is caused to produce user-perceptible feedback that notifies a user that the value of the first measurement is outside the reference range of values.

By performing electrical measurements in some or all of the ways described herein, embodiments of the present disclosure enable notification of a user based on whether a measured value is outside a reference range of values.

### BRIEF DESCRIPTION OF THE SEVERAL VIEWS OF THE DRAWINGS

FIG. 1 illustrates a context diagram for a system with integrated user notification of whether a measured value is within a specified range in accordance with embodiments described herein.

FIG. 2 illustrates a context diagram of a non-limiting example of a system with integrated user notification of whether a measured value is within a specified range in accordance with embodiments described herein.

FIG. 3A illustrates a logical flow diagram showing a process for providing a user notification of whether a measured value is within a specified range in accordance with embodiments described herein.

FIG. 3B illustrates a logical flow diagram showing a process for providing an electrical measurement device with a reference range of values based on contextual information received via the electrical measurement device in accordance with embodiments described herein.

FIG. 3C illustrates a logical flow diagram showing a process for determining a reference range of values for an electrical measurement device based on measured values for an electrical property of components in accordance with embodiments described herein.

FIG. 4A illustrates an interface of an electrical measurement device for measuring a value for comparison to a specified range in accordance with embodiments described herein.

FIG. 4B illustrates an interface of an electrical measurement device that enables configuration of a specified range in accordance with embodiments described herein.

FIG. 4C illustrates an interface of an electrical measurement device that enables configuration of a range based on previously configured ranges in accordance with embodiments described herein.

FIG. 5A is a use-case illustration of a user interacting with a system with integrated user notification of whether a measured value is within a specified range in accordance with embodiments described herein.

FIG. 5B is a use-case illustration of hands-free operation of a system that provides an alert based on whether a measured value is within a specified range in accordance with embodiments described herein.

FIG. 6 illustrates a system diagram that describes examples of computing systems for implementing embodiments described herein.

### DETAILED DESCRIPTION

Evaluating electrical components often includes confirming whether a measured value for the component such as resistance, voltage, current, etc. falls within a range of acceptable values. For example, when a photovoltaic panel has a nominal output voltage of 48 volts, the range of acceptable output voltages may be 46-50 volts.

Electrical measurement devices such as digital multimeters often include a display screen by which a user reads out a value of a measurement. Thus, workflows involving an electrical measurement device frequently require the user to look at the display screen to view and evaluate the measured value. For example, the user may use a sensor in communication with the electrical measurement device to measure a value, after which the user looks at the display screen of the electrical measurement device to read out the value, determines whether the value indicates normal operation, and records the results.

Conventional electrical measurement devices have various disadvantages. As described, the user must look at the measurement device while maintaining a position of a probe or sensor to read out the results of the measurement. Repeatedly positioning both the probe or sensor and the measurement device to view the display screen of the measurement device may cause fatigue, discomfort, or injury. When the user frequently switches attention between a display screen, a component being measured, and measurement recording equipment, the user may become distracted. Measurement errors, recording errors, and accidents may increase due to distraction. Untrained users may not understand which measured values indicate normal performance and which measured values indicate abnormal performance, leading to inconsistent reporting of the status of measured components.

The disadvantages associated with conventional electrical measurement devices are compounded in scenarios where the user needs to take repeated measurements. For example, when the user is performing quality assurance tests for multiple electrical components or assemblies, the user may repeat a similar measurement hundreds of times to determine whether each electrical component or assembly meets various performance standards. In such scenarios, the user may spend a significant amount of time switching between various components, repositioning to read a display of the electrical measurement device, determining and recording whether a value is acceptable, etc.

Embodiments of the present disclosure address these disadvantages by automatically alerting a user based on whether a measured value is outside a specified range of values. In various embodiments, the electrical measurement device is configured to alert the user without requiring the user to look at the electrical measurement device.

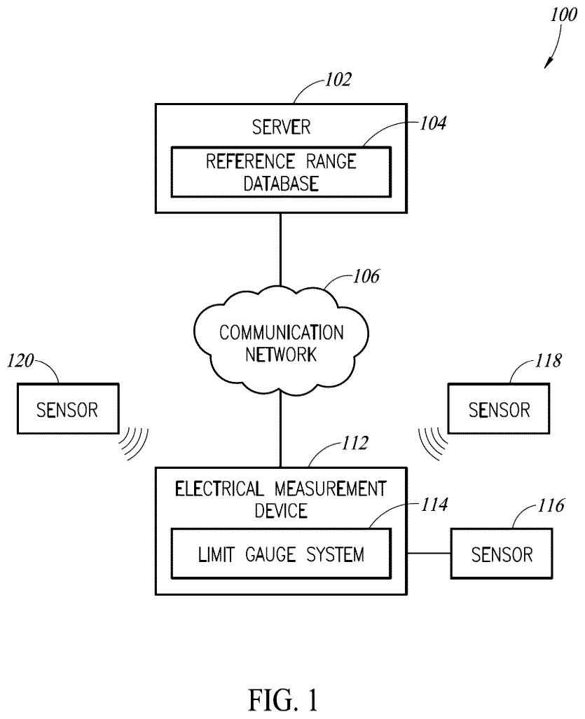

FIG. 1 illustrates a context diagram for a system 100 that produces an alert based on whether a measured value is outside a specified reference range (sometimes referred to as a “range,” a “reference range,” or a “specified range”) in accordance with embodiments described herein. System 100 includes server 102, electrical measurement device 112, sensor 116, sensor 118, and sensor 120.

Server 102 is a server, computing device, cloud computing environment, virtual machine or other computing system configured to provide electrical measurement device 112 with information relevant to determining a reference range to use, obtain information regarding measurements made using electrical measurement device 112, etc. Server 102 includes reference range database 104, which includes various information relevant to determining a range of electrical value to be used with respect to measurements to be made using electrical measurement device 112.

In some embodiments, reference range database 104 includes information to determine reference ranges. For example, reference range database 104 may include measured values of one or more electrical properties previously made for a component to be measured, measured values for one or more components having a same make, model, etc. as the component to be measured, manufacturer or user-specified nominal values for the one or more electrical properties, etc. For example, when the component to be measured is a photovoltaic panel, the reference range database 104 may include measurements previously made for the photovoltaic panel or similar photovoltaic panels. In some embodiments, server 102 provides one or more relevant measurements and a reference range of values computed using the one or more relevant measurements, or a combination thereof, to electrical measurement device 112.

In some embodiments, reference range database 104 includes a table associating various conditions with corresponding factors to scale reference ranges. For example, a photovoltaic panel's output depends upon various factors such as location, elevation, weather, time of day, age of the photovoltaic panel, duration of time since the photovoltaic panel was last cleaned, etc. Thus, a reference range reflecting nominal or acceptable output of the photovoltaic panel may accordingly depend on weather, time of day, etc. On a cloudless day, a photovoltaic panel may produce 48 volts, whereas the same photovoltaic panel may only produce 32 volts on an overcast day. Thus, in some embodiments reference range database 104 indicates that a factor such as 0.66 or ⅔ is to be applied to a reference range when the weather at the measurement location is overcast. In various embodiments, reference range database 104 includes reference values, references ranges, factors, etc. for any measurement to be made. In some embodiments, reference range database 104 may be configured to provide a sequence of reference values, reference ranges, factors, etc. for multiple components to be measured. For example, when multiple strings of photovoltaic panels are to be measured, server 102 may provide data relevant to each string from reference range database 104 in an order that corresponds to a physical layout or identification scheme of the multiple strings of photovoltaic panels. When the server 102 receives a measurement for a string in the sequence, the server 102 may respond with information relevant to calculating a reference range for a next string in the sequence.

Communication network 106 includes one or more wired or wireless networks. Server 102 and electrical measurement device 112 may communicate using communication network 106.

Electrical measurement device 112 is configured to receive a reference range of values to be used to evaluate measured values of an electrical property of one or more components and produce user-perceptible output based on whether the measured values are outside a reference range of values. In various embodiments, the user-perceptible output is produced to be perceived without requiring the user to look directly at the measurement device 112. For example, the user-perceptible output may include sound, light, vibration, etc., or any combination thereof.

While reference range database 104 is depicted as implemented using server 102, the disclosure is not so limited. For example, reference range database 104 may be implemented in part or entirely using electrical measurement device 112. In some embodiments, some or all of the operations performed by server 102 may be performed by one or more processors operating locally in the electrical measurement device 112. Furthermore, sensor 116 may be integrated into electrical measurement device 112 or may be in communication with electrical measurement device 112 via a wired or wireless connection. In various embodiments, any number of sensors such as sensor 116, sensor 118, or sensor 120 are in communication with the electrical measurement device 112. The sensors may be configured to measure different electrical properties or the same electrical property.

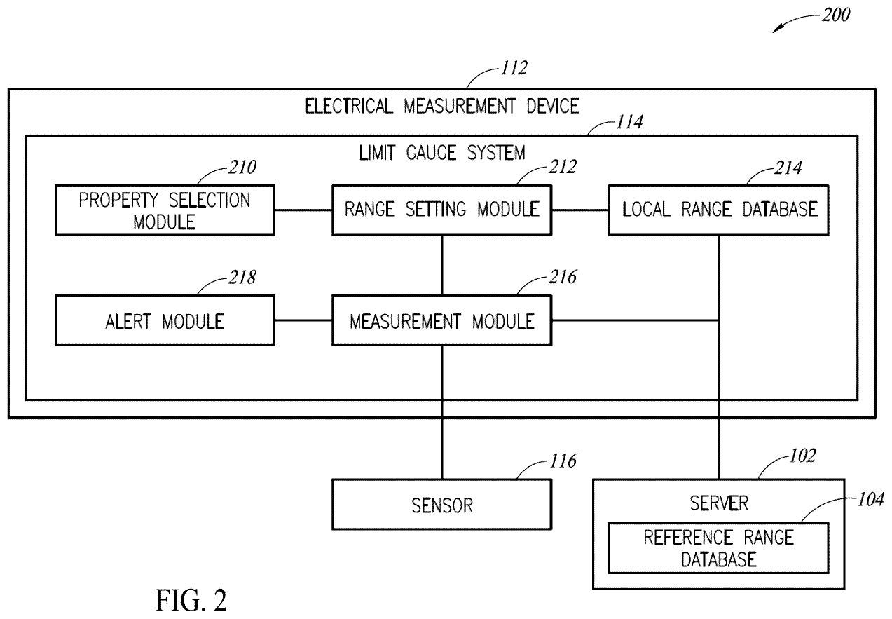

FIG. 2 illustrates a context diagram of a non-limiting example of a system 200 produces an alert based on whether a measured value is within a specified range in accordance with embodiments described herein.

System 200 includes electrical measurement device 112, sensor 116, and server 102. As will be described in more detail herein, measurement device 112 includes limit gauge system 114, which produces an alert based on whether a measured value is outside a specified reference range of values.

Limit gauge system 114 includes property selection module 210, range setting module 212, local range database 214, measurement module 216, and alert module 218. In many cases, such modules are operable according to processor-executable instructions that are stored in a memory and executed by one or more computer processors.

Property selection module 210 is used to determine a property to be measured. The property to be measured may be voltage, current, resistance, impedance, capacitance, etc. In various embodiments, property selection module 210 is used to select any electrical property that can be measured for a component.

While in various embodiments the property to be measured is an electrical property, the disclosure is not so limited. In general, a value of any measurable property may be converted into a voltage or other electrical property that may be evaluated by the electrical measurement device. Thus, in various embodiments, the property to be measured is any measurable property. The property to be measured may be a weight, size, color, shape, sound, temperature, etc. For example, the property to be measured may be a body temperature of a person measured using an infrared camera, enabling an alert to be produced when a body temperature value is outside a reference range. Multiple persons may therefore be quickly scanned for fever. Accordingly, sensor 116 may be configured to measure a value of any measurable property.

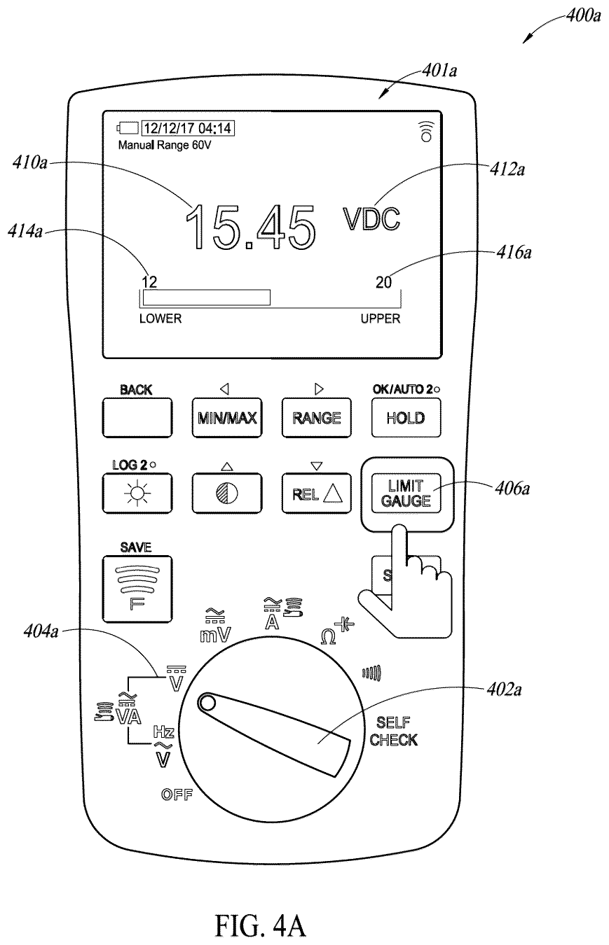

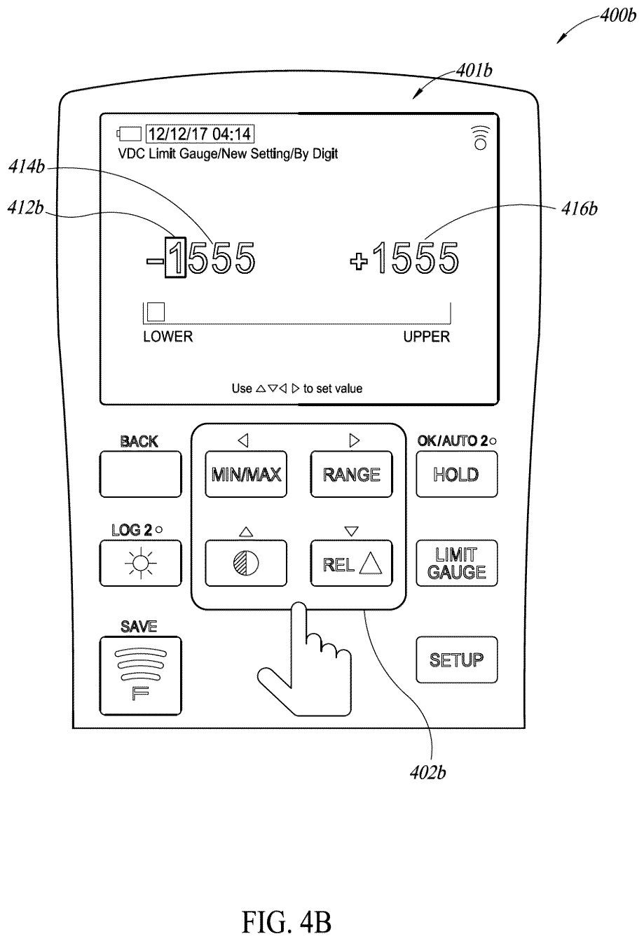

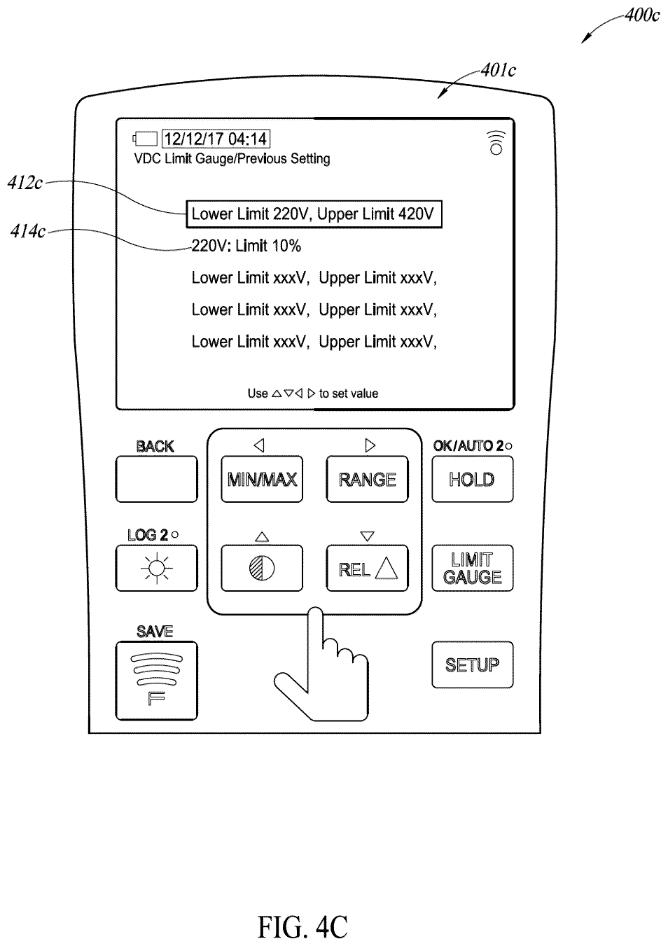

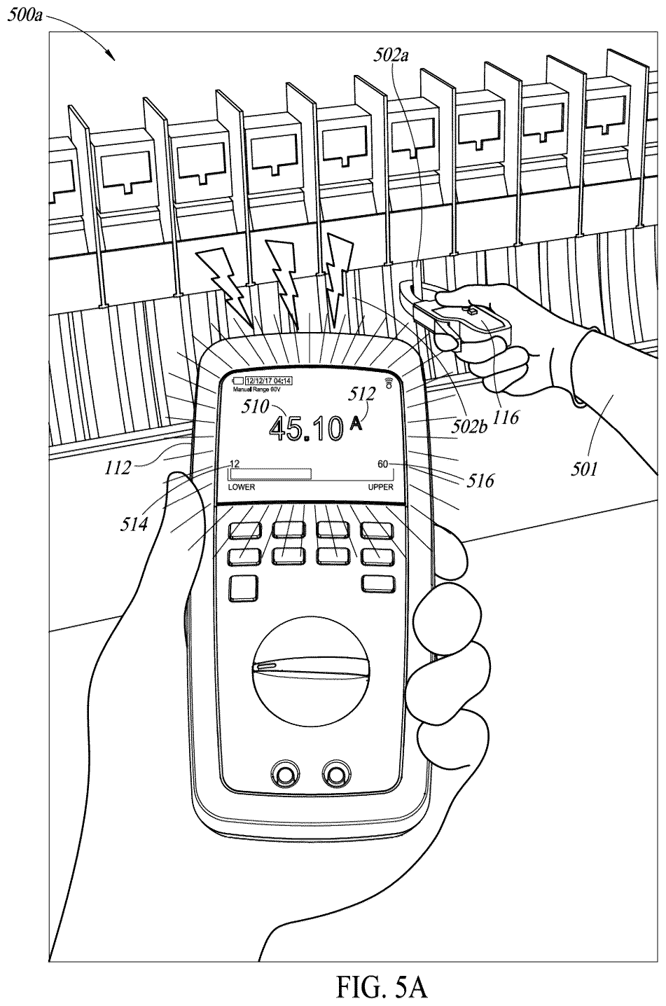

In some embodiments, the property selection module 210 obtains the property to be measured using a user input of the measurement device 112 such as a rotary knob, one or more buttons, a touch screen, a microphone, etc. As discussed herein, various sensors measuring various properties may produce a voltage as output, allowing a variety of properties to be measured via a voltage measurement. Rotary knob 402a of FIG. 4A is an example of a user input by which property selection module 210 obtains the property to be measured.

In some embodiments, the property to be measured is selected from a set of electrical properties that can be measured using the electrical measurement device 112, such as via a touchscreen. For example, when the electrical measurement device 112 can measure voltage, current, and resistance, the property to be measured may be selected from this set of electrical properties. In some embodiments, the set of electrical properties that can be measured may change based on the one or more sensors in communication with the electrical measurement device 112. When a current sensor is connected to the electrical measurement device, for example, current may be selected as the property to be measured.

Range setting module 212 is used to set a reference range of values for the measurement based on the property to be measured. In some embodiments, the range setting module 212 receives the property to be measured from the property selection module 210. The range setting module 212 may use the property to be measured to query local range database 214, reference range database 104, or a combination thereof, for an appropriate reference range. For example, when the property to be measured is voltage, preset voltage ranges may be obtained from local range database 214 and presented to the user for selection as shown in FIG. 4C. Thus, the user may provide input to reuse a reference range previously specified using the electrical measurement device 112.

The local range database 214 includes data relevant to setting the reference range of values such as the reference range itself, one or more previously measured values of the property to be measured, target values, maximum allowable deviations from the target values, or any combination thereof. In various embodiments in which the local range database 214 does not include a relevant reference range, other relevant data in local range database may be used to calculate or otherwise determine the reference range and, in cases, subsequently store it for future use.

In some embodiments, the local range database 214 associates various conditions with relevant stored data. The local range database 214 may associate a component to be measured or a feature thereof with information relevant to setting a reference range for the component. For example, local range database 214 may associate a serial number, model, location, etc. of a component with information relevant to setting a reference range for the property of the component. This may enable the measurement device 112 to automatically retrieve information to set a reference range without user input. For example, global positioning system (GPS) coordinates of a component may be associated with a reference range, such that when the measurement device 112 is located within a threshold of the GPS coordinates of the component, the measurement device 112 automatically retrieves the reference range from the local range database 214.

In some embodiments, user input that identifies the component may be received. For example, the user input may indicate a make, model, serial number, etc. of a component to be measured. The user input may be used to retrieve information to calculate or otherwise determine the reference range from local range database 214. Thus, in some cases, the user does not necessarily have to manually specify values for the reference range, e.g., as depicted in FIG. 4B.

In some embodiments, the user may modify an automatically obtained reference range. In some embodiments, the user may not have permission to modify the reference range and may be disallowed to make changes to the reference range. These features may ensure consistent use of reference ranges by users.

Measurement module 216 is used to measure the value of the electrical property of the component using sensor 116 and compare the measured value to the reference range established using range setting module 212. In some embodiments, measurements or comparisons made using measurement module 216 may be stored in local range database 214 to assist with creating or setting future reference ranges. In some embodiments, the measurements or comparisons may be provided to reference range database 104 to assist with creating or setting future reference ranges.

Alert module 218 is configured to produce alerts. For example, in some embodiments alert module 218 causes a user-perceptible output to be produced based on the comparison between the measured value of the electrical property and the reference range. When the measured value is within the reference range, the alert module 218 may produce a first output. In some cases, the first output does not cause a particular alert to the user. In other cases, the first output informs the user that the measured value is within the reference range. When the measured value is outside the reference range, the alert module 218 may produce a second output. In some cases, the second output produces a user-perceptible alert regarding the measurement deviation outside the reference range. The first or second output may include sound, light, vibration, etc., or any combination thereof.

The technology described herein pertains to alert systems that provide notifications based on measured values. In particular, the system may include one or more outputs that emit alerts in response to measured values that deviate from a reference range. The outputs may include sound, light, vibration, or any combination thereof.

In certain embodiments, the alerts emitted by the output may vary based on the degree of deviation from the reference range. For example, the frequency or decibel level of the alerting sound may change, or the color of the alerting display may vary. Additionally, the strength of the alerting vibration may be adjusted based on the degree of deviation. The degree of change in the alert may correspond to the severity of the deviation, such as using a louder or higher decibel alerting sound to indicate a more significant deviation from the reference range. The degree of deviation may determine the type and strength of the alert emitted, providing users with a clear indication of the type or severity of the situation.

In some embodiments, the user can configure aspects of the output such as a type, intensity, etc. For example, the user may prefer a light output (e.g., a green light) when the measured value is within the reference range and a combination light (e.g., a red light) and sound output when the measured value is outside the reference range. In some embodiments, the user configures the intensity of the output to better adapt the output to the measurement environment. In a library, a quiet output may be appropriate while on an oil rig a loud output may be appropriate. In some embodiments, the electrical measurement device automatically adjusts aspects of the output based on ambient conditions around the electrical measurement device such as a light level, a sound level, a time of day, etc. The intensity of the output may also vary depending on the measured value, e.g., the degree to which the measures value deviates from the reference range.

Server 102 is a server that may include reference range database 104. In various embodiments, reference range database is similar to local range database 214. In some embodiments, reference range database 104 includes information received from multiple electronic measurement devices, users, etc. In some embodiments, information in local range database 214 is periodically updated to include information in reference range database 104 or vice versa. The update may be based on a location of the electrical measurement device 112. For example, when reference range database 104 includes information relevant to determining reference ranges for components located near electrical measurement device 112, local range database 214 may be updated to include such information. In some embodiments, local range database 214 is a copy of reference range database 104 that is periodically updated to reflect changes to reference range database 104.

Sensor 116 is a sensor configured to measure one or more properties of a component. As described herein, sensor 116 may be configured to measure any measurable property of the component. In some embodiments, sensor 116 is included in electrical measurement device 112. In some embodiments, sensor 116 is in wired or wireless communication with electrical measurement device 112.

As used herein, the term “reference range database” may refer to local range database 214, reference range database 104, or any combination thereof.

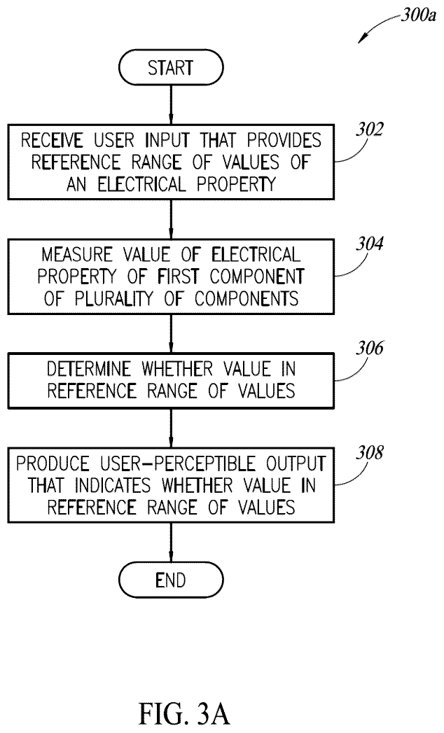

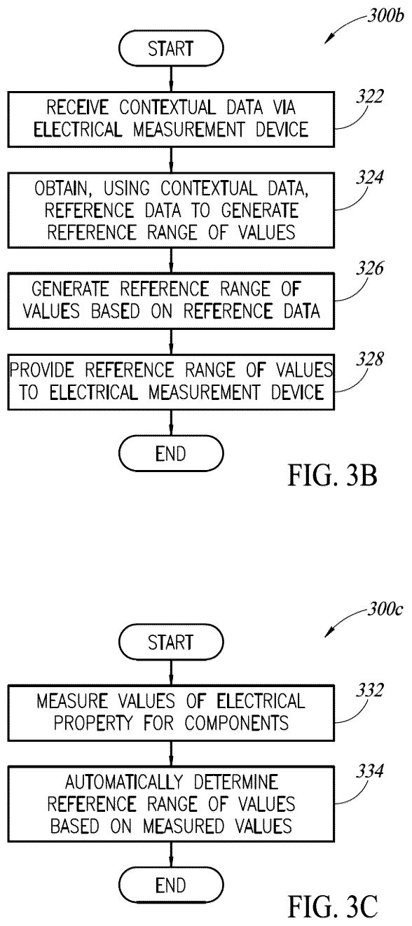

FIG. 3 illustrates a logical flow diagram showing a process 300a for providing a user notification of whether a measured value is within a specified range in accordance with embodiments described herein.

Process 300a begins, after a start block, at block 302, where user input that provides a reference range of values for an electrical property is received. As described herein, the user input may indicate the electrical property, the reference range of values, or both, or other information from which the reference range of values may be determined, e.g., identification of the component being measured.

In some embodiments, the electrical property to be measured is received based on user input provided to the electrical measurement device such as using a rotary knob.

In some embodiments, the electrical property to be measured is determined based on a component to be measured. For example, when the component to be measured is a photovoltaic cell, voltage may be the electrical property, or at least a default electrical property, to be measured. In some embodiments, the component to be measured is determined based on user input. In some embodiments, the component to be measured is automatically determined based on a location of the electrical measurement device, a data structure indicating the component to be measured, etc.

In some embodiments, the electrical property to be measured is based on a type of sensor in communication with the measurement device. For example, when a non-contact current probe, e.g., a Rogowski coil, is in communication with the measurement device, the property to be measured may be automatically determined to be current.

The reference range of values may be obtained in a variety of ways. In some embodiments, the user specifies the reference range of values using an interface of the electrical measurement device. FIG. 4B illustrates an example interface by which the user may specify the reference range of values. In some embodiments, the user inputs numerical values to set the reference range. In some embodiments, the reference range of values is selected from a previously set reference range of values, as illustrated in FIG. 4A. In various embodiments, the reference range of values is obtained using any technique described herein, such as using embodiments of local range database 214 of FIG. 2, reference range database 104 of FIG. 1, or any combination thereof. After block 302, process 300a continues to block 304.

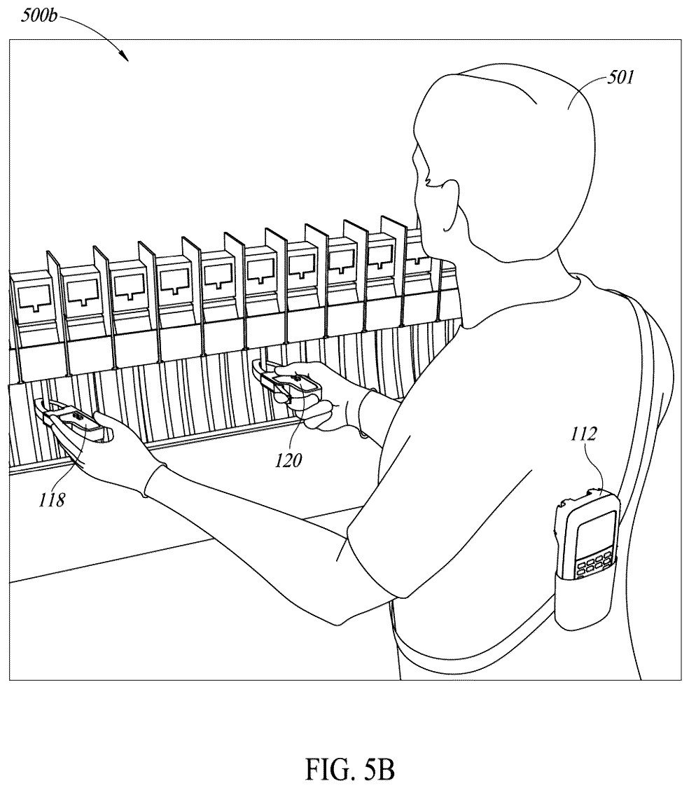

At block 304, a value of the electrical property of a first component of a plurality of components is measured. In some embodiments, the electrical property is measured using a sensor included in the electrical measurement device. In some embodiments, the electrical property is measured using a sensor in wired or wireless communication with the electrical measurement device such as sensor 116 depicted in FIG. 5. After block 304, process 300a continues to block 306.

At block 306, it is determined whether the value is in the reference range of values. In various embodiments, the determination is made by comparing the value to a lower threshold of the reference range, an upper threshold of the reference range, a target value of the reference range with a specified acceptable deviation, etc.

At block 308, user-perceptible feedback is produced to alert a user based on whether the measured value is in the reference range of values. As discussed herein, the user-perceptible feedback may include audio, light, vibration, or any combination thereof. In various embodiments, the user-perceptible output is automatically generated to indicate whether the measurement is outside the reference range of values.

In some embodiments, the electrical measurement device produces a measurement confirmation output indicating that a valid measurement has been obtained. For example, when the property to be measured is voltage, the electrical measurement device may produce a measurement confirmation output in response to measuring a non-zero voltage.

In some embodiments, the electrical measurement device produces a measurement failure output indicating that an invalid measurement has been obtained. For example, when a resistance is the property to be measured, measurement of an open circuit may indicate that an invalid measurement has been obtained.

In various embodiments, the output includes audio output. In some embodiments, a first audio output is produced when a measurement is within the reference range and a second audio output is produced when a measurement is outside the reference range. For example, a single beep may be produced when the measurement is within the reference range and multiple beeps may be produced when the measurement is outside the reference range.

In various embodiments, the audio output includes a natural language notification. For example, when the measured value is outside the reference range of values, a voice recording or synthesized voice may be produced. The natural language notification may include a natural language readout of a measured value. For example, when the measured value is 24.5 volts DC, the natural language notification may state that the measured value is 24.5 volts DC. In some embodiments, the natural language notification includes further instructions for the user based on the measured value. For example, when a measured value of a photovoltaic panel indicates that the photovoltaic panel is defective, the audio output may include instructions to be taken to report or repair the defective photovoltaic panel.

In various embodiments, visual output is configured such that the user may determine whether the measurement was within the reference range without directly looking at the measurement device. For example, the visual output may include emitting a green light when the measurement is within the reference range. The visual output may include emitting a red light when the measurement is outside the reference range. Such light may be perceived in a user's peripheral vision. In various embodiments, several degrees of variance from the reference range may be indicated using different visual outputs. For example, a red visual output may indicate that a measurement is outside of the reference range, a blinking red visual output may indicate that the measurement is more than a threshold value outside of the reference range, etc. A green visual output may indicate that the measurement is within a subrange of the reference range, and one or more shades of green, yellow, or red may indicate that the measurement value is in a corresponding subrange of the reference range or a subrange of a range of values outside of the reference range. Thus, the measurement device can indicate a degree to which the measurement varies from the reference range or a reference value based on a color, pattern of flashes, or any combination thereof.

In various embodiments, the user may configure aspects of the output such as by selecting a type of output to be produced when a measured value is inside or outside the reference range of values, configuring various aspects of the output such as intensity, etc. For example, an intensity of sound output may relate to volume, frequency, etc., while an intensity of visual output may relate to brightness, color, flashing patterns, etc.

In some embodiments, an aspect of the output varies based on a distance or amount of a measured value from the reference range, or a position of the measured value within the reference range. For example, the output may increase in intensity, frequency, etc. as the measured value deviates further outside of the reference range or from a reference value in the reference range. After block 308, process 300a ends at an end block.

While process 300a describes measuring a value of an electrical property of a first component of a plurality of components, the disclosure is not so limited. In various embodiments, the reference range may be used to measure any number of components of the plurality of components. For example, the same reference range may be used to measure several strings of solar panels at a voltage combiner, several components to be tested as part of quality assurance in an assembly line, etc. In some embodiments, multiple components may be measured without setting additional reference ranges or other configuration for each measurement performed. While not shown in FIG. 3, after block 308 process 300a may return to block 304, where another component in the plurality of components is measured. Blocks 304, 306, and 308 may be sequentially repeated any number of times to measure any number of components using the reference range of values.

FIG. 3B illustrates a logical flow diagram showing a process 300b for providing an electrical measurement device with a reference range of values based on contextual information received via the electrical measurement device in accordance with embodiments described herein. In various embodiments, block 302 of process 300a employs embodiments of process 300b to obtain a reference range of values.

Process 300b begins, after a start block, at block 322, where contextual data is received via the electrical measurement device.

In various embodiments, the contextual data identifies a component to be measured, the electrical measurement device, the user of the electrical measurement device, or any combination thereof. For example, the contextual data may include an asset identification number for a photovoltaic panel to be measured, as well as an identity of the electrical measurement device and the user of the electrical measurement device. After block 322, process 300b continues to block 324.

At block 324, the contextual data is used to obtain reference data with which to generate a reference range of values. The contextual data may correspond to one or more keys in a database such as reference range database 104. The reference data may correspond to one or more values in the database that are associated with the one or more keys.

In some embodiments wherein the contextual data identifies the component to be measured, the reference data includes values of measurements of the electrical property for the component or similar components, a nominal value of the electrical property of the component, a reference range of values for the electrical property of the component, etc. In various embodiments wherein the contextual data identifies the electrical measurement device, the reference data includes information associated with the electrical measurement device. In some embodiments, the reference data includes a schedule of one or more reference ranges to be sequentially used by the electrical measurement device to measure one or more components. For example, the electrical measurement device may be designated to measure certain components during a selected time period such that corresponding reference ranges of values may be obtained.

In some embodiments wherein the contextual information identifies the user of the electrical measurement device, the reference data includes a schedule of one or more reference ranges to be sequentially used by the user of the electrical measurement device to measure one or more components. For example, the user may be designated to measure certain components during a selected time period such that corresponding reference ranges of values may be obtained. After block 324, process 300b continues to block 326.

At block 326, a reference range of values is generated based on the reference data. As described herein, the reference data may already include the reference range of values. In various embodiments, however, the reference data does not include the reference range of values but includes, for example, a nominal value for an electrical property. In some embodiments, the reference range of values is generated by applying a configurable maximum deviation to the nominal value. For example, when the nominal value for the electrical property is 220 volts and the maximum deviation is 10%, the generated reference range of values is 198 to 242 volts. The maximum deviation may be a preset value or may be configured by a user. After block 326, process 300b continues to block 328.

At block 328, the reference range of values is provided to the electrical measurement device. After block 328, process 300b ends at an end block.

FIG. 3C illustrates a logical flow diagram showing a process 300c for determining a reference range of values for an electrical measurement device based on measured values for an electrical property of components in accordance with embodiments described herein. In some cases, a nominal value or reference range for a plurality of components is not known before the plurality of components is to be measured. For example, output voltages of photovoltaic panels depend on various dynamic factors such as weather, altitude, debris on the panels, etc. Thus, components may be measured on-site using the electrical measurement device to determine a reference range of values for the components. In various embodiments, block 302 of process 300a employs embodiments of process 300c to obtain a reference range of values.

Process 300c begins, after a start block, at block 332, where values of an electrical property are measured for one or more components. In various embodiments, any number of components are measured. After block 332, process 300c continues to block 334.

At block 334, a reference range of values is automatically determined based on the measured values. As discussed herein, the reference range of values may be determined by applying one or more factors to a metric of the measured values. For example, the reference range of values may be determined by applying a maximum percent or absolute deviation to an average of the measured values.

In various embodiments, the reference range is dynamically updated based on subsequently measured values for components. For example, the reference range may be based on a metric computed using the measured values such as a running average of the measured values. In some embodiments, outlying values that deviate from the metric by more than a configurable threshold, such as a selected number of standard deviations or an absolute value, are not used to calculate the metric.

FIG. 4A illustrates an interface 400a for measuring a value for comparison to a reference range of values in accordance with embodiments described herein. Interface 400a includes a measurement interface 401a, a limit gauge button 406a, rotary knob 402a, and a measurement type indicator 404a. Measurement interface 401a includes a measurement value 410a, a measurement unit 412a, a lower range threshold 414a, and an upper range threshold 416a. As depicted in FIG. 4A, rotary knob 402a selects measurement type indicator 404a, which indicates that a “volts direct current” (VDC) measurement is being taken. Accordingly, measurement interface 401a indicates that the measurement unit 412a is VDC. As depicted in the example shown in FIG. 4A, lower range threshold 414a is 12 volts, upper range threshold 416a is 20 volts, and measurement value 410a is 15.45 volts. Measurement value 410a is therefore within the reference range specified by the lower range threshold 414a and the upper range threshold. Thus, in some embodiments, an output indicating that the measurement value 410a is within the reference range is produced.

Limit gauge button 406a may be used to initiate configuration of the reference range or to initiate use of the limit gauge with a previously configured reference range. In various embodiments, selection of limit gauge button 406a causes the electrical measurement device to enter various alternate operation modes to perform functions related to the limit gauge. As discussed herein, the various alternate operation modes may include a mode for performing a measurement relative to a reference range, a mode for configuring a reference range, a mode for recalling a previously configured reference range, a mode for scrolling through recently used reference ranges, a mode for loading the last used reference range, etc.

In various embodiments, a functionality of limit gauge button 406a is based on a current state of the electrical measurement device. For example, when the limit gauge is deactivated, selection of the limit gauge button may cause the limit gauge to be activated, while when the limit gauge is activated, selection of the limit gauge button may cause the limit gauge to be deactivated. In another example, various settings related to use of the limit gauge with respect to a type of measurement selected using rotary knob 402a may be displayed in response to selection of the limit gauge button.

In some embodiments, selection of limit gauge button 406a causes the electrical measurement device to display various alternate operation modes relating to the limit gauge. For example, the electrical measurement device may display options to enter a measurement mode, a reference range configuration mode, or a reference range selection mode. The user may then select the operation mode to be entered.

In some embodiments, selection of limit gauge button 406a causes the limit gauge to enter a measurement mode. For example, selection of limit gauge button 406a may cause measurement interface 401a to be displayed. In some embodiments in which the electrical measurement device is already in the measurement mode, selection of the limit gauge button 406a disables the limit gauge such that measurements may be made without using the limit gauge.

In some embodiments, selection of limit gauge button 406a causes the electrical measurement device to enter a reference range configuration mode. For example, selection of limit gauge button 406a may cause reference range configuration interface 401b of FIG. 4B to be displayed such that the user may configure the reference range.

In some embodiments, selection of limit gauge button 406a causes the electrical measurement device to enter a reference range selection mode. Selection of limit gauge button 406a may, for example, cause a list of previously configured reference ranges to be displayed for selection as illustrated in reference range selection interface 401c of FIG. 4C. The user may then select a previously configured reference range. In some embodiments, selection of the previously configured reference range causes a measurement interface such as measurement interface 401a to be displayed and causes an alert to be produced based on whether a measured value is within the selected reference range.

In some embodiments, the list of previously configured reference ranges is obtained based on a setting of rotary knob 402a. In FIG. 4A, rotary knob 402a is set to select measurement type indicator 404a, which in this case indicates volts direct current. Accordingly, the electrical measurement device displays previously configured reference ranges configured for volts direct current, as depicted in FIG. 4C. In various embodiments, the previously configured reference ranges are retrieved for another measurement type selected using the rotary knob 402a such as volts alternating current, millivolts alternating current, millivolts direct current, amps, ohms, capacitance, etc. In some embodiments, at least one of the previously configured reference ranges is obtained via another computing device such as server 102. As discussed herein, relevant reference ranges may be provided to the electrical measurement device based on contextual information such as a location of the electrical measurement device, an identity of the electrical measurement device, an identity of a user of the electrical measurement device, etc.

In some embodiments, the list of previously configured reference ranges is obtained based on a property measurable by a sensor in communication with the electrical measurement device. For example, when an irradiance sensor is connected to the electrical measurement device, selection of the limit gauge button 406a may enable selection of a previously configured reference range for certain irradiance measurements or selection of a reference range for certain irradiance measurements despite irradiance not being a measurement type selectable using rotary knob 402a. Thus, configuration or selection of reference ranges is not necessarily limited to measurement types selectable using rotary knob 402a.

In various embodiments, user input patterns involving limit gauge button 406a cause the electrical measurement device to perform various functionalities related to the limit gauge. In some embodiments for example, the last used reference range is selected for use in response to receiving a double click of the limit gauge button 406a. In some embodiments, various recently used reference ranges are cycled through in response to receiving a long press of limit gauge button 406a. In some embodiments, a reference range is obtained based on contextual information such as via server 102 when the limit gauge button 406a is concurrently pressed with another button such as a button to initiate remote communications.

FIG. 4B illustrates an interface 400b for an electrical measurement device that enables user-configuration of a reference range of values in accordance with embodiments described herein. Interface 400b includes reference range configuration interface 401b and inputs 402b. Reference range configuration interface 401b includes lower range threshold 414b, upper range threshold 416b, and cursor 412b. To configure the reference range, a user uses inputs 402b to navigate the cursor 412b to a digit of the lower range threshold 414b or the upper range threshold 416b. The user then uses inputs 402b to select a value for the selected digit. While the lower range threshold 414b and the upper range threshold 416b are shown as including four digits each, the disclosure is not so limited. In various embodiments, the lower range threshold 414b or the upper range threshold 416b may include different numbers of digits.

In some embodiments, inputs 402b may be used to specify a target value and a threshold deviation from the target value instead of lower range threshold 414b and upper range threshold 416b. For example, the user may indicate a target value of 220 volts with a maximum deviation of 10%. Thus, the equivalent lower range threshold is 198 volts and the equivalent upper range threshold is 242 volts. In various embodiments, the interface 400c may be used to select a maximum deviation by a percentage or absolute value.

In some embodiments, inputs 402b are physical buttons. Because the user may be wearing gloves to protect against injury while measuring high-power components or other hazardous objects, it is often advantageous for inputs 402b to be physical buttons or other inputs operable with a gloved hand. Nonetheless, in some embodiments, inputs 402b are provided using a touchscreen, virtual keyboard, or other technique for providing virtual buttons.

In some embodiments, the user sets the target value, the maximum deviation, or both, by measuring an electrical property of one or more components. In some embodiments, the measured values may be averaged to produce the target value. Furthermore, a plurality of measured values may be used to automatically calculate a maximum deviation based on a highest value measured, a lowest value measured, a variance of the plurality of values, or any other statistical metric of the plurality of values. In some embodiments, the electrical measurement device prompts the user to input the one or more measured values using interface 400b or another input mechanism.

FIG. 4C illustrates an interface 400c for an electrical measurement device that enables configuration of a range based on previously configured ranges in accordance with embodiments described herein. Interface 400c includes reference range selection interface 401c. Reference range selection interface 401c, in this example, includes selected reference range 412c and unselected reference range 414c. As shown in FIG. 4C, selected reference range 412c includes a lower limit of 220 volts and an upper limit of 420 volts. Unselected reference range 414c includes a target value of 220 volts and a maximum deviation of 10%. As described herein, the previous settings may include settings previously set using the electrical measurement device. In various embodiments, the electrical measurement device obtains one or more of the reference ranges displayed using reference range selection interface 401c via reference range database 104 of FIG. 1. The electrical measurement device may automatically receive a reference range based on a component to be measured. For example, measurements or statuses of the component to be measured may be available via reference range database 104.

FIG. 5A is a use-case illustration 500a of a user interacting with a system that produces an alert based on whether a measured value is outside a specified range in accordance with embodiments described herein.

In FIG. 5A, user 501 uses sensor 116 in communication with electrical measurement device 112 to measure current values of string 502a and string 502b in a combiner box for photovoltaic panel strings. Measurement device 112 includes an interface that shows measurement value 510, measurement type 512, lower range threshold 514, and upper range threshold 516. In the example depicted in FIG. 5, the lower range threshold 514 is 12 amps, the upper range threshold 516 is 60 amps, and the measurement value 510 is 45.10 amps. Because the measurement is within the range defined by the lower range threshold and the upper range threshold, measurement device 112 produces output indicating that the measurement is within the specified range, or alternatively produces no particular alerting output. For example, the measurement device may produce visual output, sound output, or a combination thereof.

FIG. 5B is a use-case illustration 500b of hands-free operation of a system that provides an alert based on whether a measured value is within a specified range in accordance with embodiments described herein. While in FIG. 5A user 501 is depicted as holding and possibly viewing the measurement device 112, embodiments are not so limited. As discussed herein, measurement device 112 produces output that allows user 501 to determine whether measurement value is within the reference range without necessarily looking at or holding the electrical measurement device 112. Accordingly, the device 112 may be positioned in various locations such as resting on the ground or another surface, removably attached to a garment or accessory of the user 501 as illustrated in FIG. 5B, inside a bag or carrier, etc. Thus, embodiments of the present disclosure may allow the user 501 to better focus on safe and correct placement of one or multiple sensors such as sensor 118 and sensor 120 instead of holding electrical measurement device 112 or reading a measurement value displayed using the electrical measurement device 112. A measured current or another property of each of the strings in the combiner box may therefore be quickly and safely measured and evaluated using any number of sensors in communication with the electrical measurement device 112, which is configured to receive concurrent messages from multiple sensors for respective measurements, e.g., based on a suitable wireless communication protocol that allows concurrent communication and reception of messages from multiple connected sensing devices, such as: interference alignment based protocols, channel capture based protocols, concurrent carrier sense multiple access protocols, etc. In one embodiment, electrical measurement device 112 and sensing devices are configured to use the latest Bluetooth™ standard, which has improved concurrent capabilities, higher bandwidth, longer range, and better interference resistance, and more reliable concurrent connections. In this way, the disclosed technical solution tremendously improved both the safety and productivity for users.

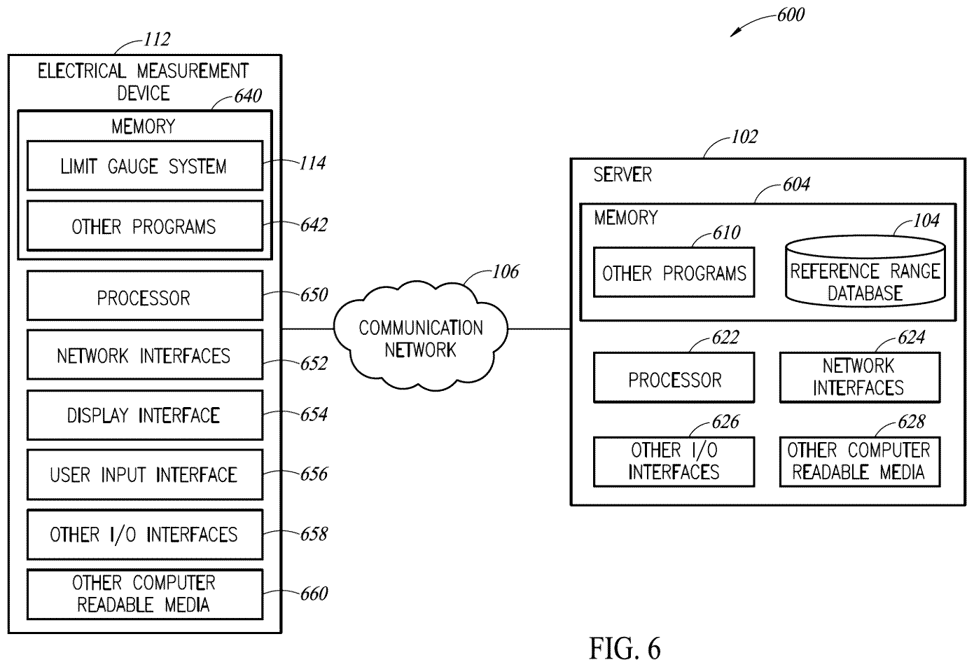

FIG. 6 illustrates a system diagram that describes examples of computing systems for implementing embodiments described herein.

As described herein, electrical measurement device 112 is a computing device that can perform functionality described herein for notifying a user when a measurement value is in a specified range. One or more special purpose computing systems may be used to implement electrical measurement device 112. Accordingly, various embodiments described herein may be implemented in software, hardware, firmware, or in some combination thereof. Electrical measurement device 112 in this example includes memory 640, one or more processors 650, network interfaces 652, display interface 654, user input interface 656, other input/output (I/O) interfaces 658, and other computer-readable media 660.

Processor 650 includes one or more processors, processing units, programmable logic, circuitry, or other computing components that are configured to perform embodiments described herein or to execute computer instructions to perform embodiments described herein. In some embodiments, processor 650 includes a single processor that operates individually to perform actions. In other embodiments, processor 650 includes a plurality of processors that operate to collectively perform actions, such that one or more processors may operate to perform some, but not all, of such actions.

Memory 640 may include one or more various types of non-volatile or volatile storage technologies. Examples of memory 640 include, but are not limited to, flash memory, hard disk drives, optical drives, solid-state drives, various types of random-access memory (“RAM”), various types of read-only memory (“ROM”), other computer-readable storage media (also referred to as processor-readable storage media), or other memory technologies, or any combination thereof. Memory 640 may store information, including computer-readable instructions that are utilized by processor 650 to perform actions, including at least some embodiments described herein.

Memory 640 may store processor-executable instructions that, when executed, provide the limit gauge system 114. As described herein, limit gauge system 114 enables the electrical measurement device 112 to alert a user based on whether a measured value is within a reference range of values.

Memory 640 may also store other programs 642, which may include operating systems, user applications, or other computer programs.

Network interfaces 652 are configured to communicate with other computing devices, such as server 102, via communication network 106. Network interfaces 652 include transmitters and receivers (not illustrated) to send and receive data from electrical measurement device 112 or other devices.

Display interface 654 may include one or more screens, touchscreens, lights, etc.

User input interface 656 may include one or more buttons, touchscreens, microphones, etc., for receiving user input.

Other I/O interfaces 658 may include interfaces for various other input or output devices, such as audio interfaces, other video interfaces, USB interfaces, physical buttons, keyboards, haptic interfaces, tactile interfaces, or the like. Other computer-readable media 660 may include other types of stationary or removable computer-readable media, such as removable flash drives, external hard drives, or the like.

Processor 622, network interfaces 624, memory 604, other I/O interfaces 626, and other computer-readable media 628 of server 102 are in various embodiments similar to corresponding components discussed with respect to electrical measurement device 112. Memory 604 may include other programs 610, which is in various embodiments similar to other programs 642. Memory 604 may also include reference range database 104, which stores information relevant to determining reference ranges of values for a component to be measured. In some embodiments, reference range database 104 is implemented in part or in whole using memory 640 of electrical measurement device 112.

The following is a list of various technical features, which may implemented separately or in any selected combinations to achieve the disclosed technical solution and effects.

An electrical measurement device may include: one or more sensors configured to measure an electrical property; an alert module (218) configured to produce alerts; one or more processors; and/or a storage device that stores instructions executable by the one or more processors to configure the one or more processors to: set a reference range of values of the electrical property; receive a first measurement of the electrical property of a first component of a plurality of components; determine whether a value of the first measurement is outside the reference range of values; and/or in response to determining that the value of the first measurement is outside the reference range of values, cause the alert module to produce an alert indicating that the value of the first measurement is outside the reference range of values.

The electrical measurement device may include a physical user input component on a physical user interface of the measurement device. The device may be configured to enter or exit a first mode of operation to set the reference range of values in response to a first type of user input via the physical user input component, or enter or exit a second mode of operation to be standby for determining that the at least one of the respective measurements is outside the reference range of values in response to a second type of user input via the physical user input component, or enter or exit a third mode of operation to measure or test the physical property in response to a third type of user input via the physical user input component.

A system may include: sensors or sensing devices configured to measure an electrical property; and an electrical measurement device wirelessly coupled to the sensors and configured to: receive respective measurements of the electrical property; determine that at least one of the respective measurements is outside a specified reference range of values; and/or in response to determining that the at least one of the respective measurements is outside the specified reference range of values, produce an alert that indicates that the at least one of the respective measurements is outside the specified reference range of values.

A method performed using an electrical measurement device may include: obtaining one or more reference values for an electrical property of one or more reference components; determining, based on the one or more reference values, a reference range of values for the electrical property; measuring, using an electrical measurement device, values of the electrical property of a plurality of components; determining whether the values are in the reference range of values; and producing an alert based on whether the values are in the reference range of values.

The method may have one or more of the following features, including: measuring, using the electrical measurement device, the electrical property of the one or more reference components; determining a target value based on the one or more reference values; determining a maximum deviation from the target value; determining the reference range of values based on the target value and the maximum deviation from the reference value; wherein the one or more reference components are in the plurality of components; obtaining the one or more reference values for one or more reference components having a same nominal value for the electrical property as at least one component of the plurality of components; causing a transducer to produce a first output in response to determining that the value is in the reference range of values; or causing a transducer to produce a second output in response to determining that the value is not in the reference range of values.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electrical measurement device, comprising:
one or more sensors configured to measure an electrical property;
an alert module configured to produce alerts;
one or more processors; and
a storage device that stores instructions executable by the one or more processors to configure the one or more processors to:
set a reference range of values of the electrical property;
receive, via the one or more sensors, a first measurement of the electrical property of a first component of a plurality of components;
determine whether a value of the first measurement is outside the reference range of values; and
in response to determining that the value of the first measurement is outside the reference range of values, cause the alert module to produce an alert indicating that the value of the first measurement is outside the reference range of values.

2. The measurement device of claim 1, wherein the one or more processors are further configured to:
concurrently receive, from the one or more sensors, a second measurement of the electrical property of a second component of the plurality of components;
determine whether a value of the second measurement is outside the reference range of values; and
in response to determining that the value of the second measurement is outside the reference range of values, cause the alert module to produce the alert indicating that the value of the second measurement is outside the reference range of values.

3. The electrical measurement device of claim 1, further comprising one or more physical user input components, wherein the one or more processors are further configured to use user input received via the one or more physical user input components to set the reference range of values.

4. The electrical measurement device of claim 1, wherein at least one of the one or more sensors is integrated in the electrical measurement device.

5. The electrical measurement device of claim 1, further comprising one or more physical user input components, wherein user input is obtained via the one or more physical user input components and specifies a lower threshold value and an upper threshold value from which the reference range of values is determined.

6. The electrical measurement device of claim 5, wherein the one or more processors are further configured to apply a factor to at least one of the lower threshold value or the upper threshold value to determine the reference range of values, and wherein the factor is based on contextual information received via the electrical measurement device.

7. The electrical measurement device of claim 1, further comprising one or more physical user input components, wherein user input is obtained using the one or more physical user input components and specifies a reference value and a maximum deviation from the reference value, and wherein the reference range of values is determined based on the reference value and the maximum deviation.

8. The electrical measurement device of claim 1, wherein the one or more processors are configured to:
obtain one or more reference measurements of the electrical property of one or more components of the plurality of components, and
determine the reference range of values based on the one or more reference measurements.

9. A system for test or measurement, comprising:
a plurality of sensors, configured to measure a physical property; and
a measurement device, wirelessly coupled to the plurality of sensors and configured to:
receive, via the plurality of sensors, respective measurements of the physical property;
determine that at least one of the respective measurements is outside a reference range of values; and
in response to determining that the at least one of the respective measurements is outside the reference range of values, produce an alert that indicates that the at least one of the respective measurements is outside the reference range of values.

10. The system of claim 9, wherein the respective measurements are first respective measurements and the measurement device is further configured to:
receive, via the plurality of sensors, second respective measurements of the physical property;
determine that at least one of the second respective measurements is outside the reference range of values; and
in response to determining that the at least one of the respective second measurements is outside the reference range of values, produce the alert that indicates that the at least one the second respective measurements is outside the reference range of values.

11. The system of claim 1, further comprising a server in communication with the measurement device, and wherein the measurement device is configured to receive the reference range of values via the server.

12. The system of claim 1, wherein the alert further indicates an identity of a sensor in the plurality of sensors that obtained the at least one of the respective measurements outside the reference range of values.

13. The system of claim 1, wherein the measurement device obtains the reference range of values by being further configured to:
obtain a lower threshold value and an upper threshold value for the reference range of values;
determine a factor to apply to at least one of the lower threshold value or the upper threshold value based on contextual information associated with an environment of the measurement device; and
apply the factor to at least one of the lower threshold value or the upper threshold value to obtain the reference range of values.

14. The system of claim 1, further comprising a physical user input component on a physical user interface of the measurement device, wherein the measurement device is configured to enter or exit a first mode of operation to set the reference range of values in response to a first type of user input via the physical user input component, or enter or exit a second mode of operation to be standby for determining that the at least one of the respective measurements is outside the reference range of values in response to a second type of user input via the physical user input component, or enter or exit a third mode of operation to measure or test the physical property in response to a third type of user input via the physical user input component.

15. A method, performed using an electrical measurement device, for test or measurement, the method comprising:
obtaining one or more reference values for an electrical property of one or more reference components;
determining, based on the one or more reference values, a reference range of values for the electrical property;
measuring, using the electrical measurement device, values of the electrical property of a plurality of components;
determining whether the values are in the reference range of values; and
producing an alert based on whether the values are in the reference range of values.

16. The method of claim 15, wherein obtaining the one or more reference values comprises:
measuring, using the electrical measurement device, the electrical property of the one or more reference components.

17. The method of claim 15, wherein determining the reference range of values for the electrical property comprises:
determining a target value based on the one or more reference values;
determining a maximum deviation from the target value; and
determining the reference range of values based on the target value and the maximum deviation from the reference value.

18. The method of claim 15, wherein the one or more reference components are in the plurality of components.

19. The method of claim 15, wherein obtaining the one or more reference values comprises:
obtaining the one or more reference values for one or more reference components having a same nominal value for the electrical property as at least one component of the plurality of components.

20. The method of claim 15, wherein producing the alert comprises:
causing a transducer to produce a first output in response to determining that the value is in the reference range of values; or
causing a transducer to produce a second output in response to determining that the value is not in the reference range of values.
